(19) United States
(12) Patent Application Publication
(10) Pub. No.: US 2008/0299700 A1
(43) Pub. Date: Dec. 4, 2008

(54) METHOD FOR FABRICATING PHOTODIODE

(76) Inventors: Bang-Chiang Lan, Taipei City (TW); Tzung-I Su, Yun-Lin County (TW); Chien-Nan Kuo, Taoyuan County (TW); Chao-An Su, Kaohsiung County (TW); Heng-Ching Lin, Hsinchu City (TW); Shih-Wei Li, Taipei County (TW); Wei-Chin Hung, Hsinchu City (TW)

Correspondence Address: NORTH AMERICA INTELLECTUAL PROPERTY CORPORATION, P.O. BOX 506, MERRIFIELD, VA, 22116, US

(21) Appl. No.: 11/754,355

(22) Filed: May 28, 2007

(51) Int. Cl. H01L 21/00

(52) U.S. Cl. 438/98; 257/E27.133

(57) ABSTRACT

A method of fabricating photodiode includes: a substrate comprising a well is provided, next, a first doping region is formed in the well, following that a conductive layer is formed on the surface of the first doping region by an epitaxial growth process, meanwhile, the conductive layer is in-situ doped to form a second doping region in the conductive layer. The method for fabricating the photodiode in the present invention can prevent the lattice structure from being damaged during the high dozes implantation process. Therefore, the dark current can be reduced and the sensitivity of the photodiode will be increased.

### BACKGROUND OF THE INVENTION

1. Field of the Invention

The present invention relates generally to methods of fabricating a photodiode and more particularly, to methods which can prevent the lattice structure of the photodiode from being damaged during the high-energy implantation process.

2. Description of the Prior Art

A complementary metal-oxide-semiconductor (CMOS) image sensor is a common solid-state image sensor. The CMOS image sensors have been gradually replacing charge-coupled devices (CCD) over time. Because the fabricating process of a CCD is complicated, and the process is difficult to be integrated into the control circuit or the signal processing system, the size of the CCD is not easy to reduced. Furthermore the CCD consumes a high amount of power. On the contrary, the CMOS image sensors are manufactured by traditional semiconductor manufacturers, and have lower costs and smaller sizes than regular image sensors. Furthermore, CMOS image sensors have high quantum efficiency and low read-out noise, making its usage popular with PC cameras and digital cameras.

The CMOS sensor pixel cell includes a photodiode in an underlying portion of the substrate. A transfer gate is provided for transferring photoelectric charges generated in the photodiode to a floating diffusion region. Typically, the floating diffusion region is coupled to a gate of a source follower transistor. The source follower transistor provides an output signal to a row select access transistor having a gate. A reset transistor having a gate resets the floating diffusion region to a specified charge level before each charge transfer from the photodiode. In addition, N-type doped source/drain regions are provided on either side of the transistor gates. The floating diffusion region adjacent the transfer gate is also N-type.

The photodiode has a PNP junction region consisting of a surface P+ pinning layer, an N-type photodiode region and the P-type substrate. The photodiode includes two P-type regions so that the N-type photodiode region can be fully depleted. In addition, the photodiode sends signal data according to photo current from the photo sensor area. For example, light current serves as signal data which is generated when the photo sensor area is illuminated, and dark current is noise which is generated when the photo sensor area is without light. Therefore, the photodiode utilizes the magnitude of the signal or noise to generate the signal data.

FIGS. 1 to 6 are schematic diagrams of a fabrication method for a CMOS image sensor according to prior art. As shown in FIG. 1, first, a substrate 10 containing a P-type well is provided. Then, a STI structure 12 is formed in the substrate 10, and by the implantation process, P-type dopant is added in the substrate 10 to form a P-type doping region 14 in order to adjust the threshold voltage of the transfer gate and pin a surface voltage in the photodiode.

As shown in FIG. 2, a dielectric layer (not shown) is formed on the substrate 10. Then, a conductive layer (not shown) is formed on the dielectric layer. Following that, an etching process is performed to etch the dielectric layer and the conductive layer to form gates of every transistor on the substrate 10. For example, the transfer gate in the FIG. 2 includes an insulator 16 and a conductor 18.

As shown in FIG. 3, an insulator 20 is formed covering the substrate 10 and the conductor 18 totally. After that, as shown in FIG. 4, a photodiode region 23 is defined by a first photoresist 22 which is patterned, and N-type ions are implanted into the substrate 10 under the photodiode region 23 to form a N-type doping region 24.

As shown in FIG. 5, the first photoresist 22 is removed, and the photodiode region 23 is defined by a second photoresist 26 which is patterned to implant P-type ions in the substrate 10 to form a P-type doping region 28. For now, the process of fabricating the photodiode is finished.

After removing the second photoresist 26, as shown in FIG. 6, a N-type doping region 30 is formed adjacent to a side of the conductor 18 by using a third photoresist (not shown) as mask. For now, the process of fabricating the CMOS image sensor is finished.

In addition, another fabricating process of the CMOS image sensor is disclosed in the US patent. (US publication No. 2006/0138471) The fabricating process is shown in FIG. 7 to FIG. 13.

As shown in FIG. 7, first, a substrate 110 containing a P-type well is provided. Then, a STI structure 12 is formed in the substrate 110, and by using the implantation process, P-type dopant is added in the substrate 110 to form a P-type doping region 114 in order to adjust the threshold voltage of the transfer gate and pin a surface voltage in the photodiode.

As shown in FIG. 8, a dielectric layer (not shown) is formed on the substrate 110. Then, a conductive layer (not shown) is formed on the dielectric layer. Following that, an etching process is performed to etch the dielectric layer and the conductive layer to form gates of every transistor on the substrate 110. For example, the transfer gate in the FIG. 8 includes an insulator 116 and a conductor 118.

As shown in FIG. 9, an insulator 120 is formed covering the substrate 110 and the conductor 118 totally. After that, as shown in FIG. 10, a photodiode region 123 is defined by a first photoresist 122 which is patterned, and a wet etching process is performed to remove part of the insulator 120, then N-type ions are implanted into the substrate 110 under the photodiode region 23 to form a N-type doping region 124.

As shown in FIG. 11, after removing the first photoresist 122, a single-crystal silicon layer 132 is formed on the surface of the photodiode region 123. Following that, a photoresist 126 is formed, which is patterned. Then a P-type doping region 128 is formed by the implantation process. For now, the process of fabricating the photodiode is finished.

After removing the photoresist 126, as shown in FIG. 13, a spacer 134 is formed on the conductor 118. Finally, a N-type doping region 130 is formed adjacent to a side of the conductor 118 by using a third photoresist (not shown) as mask. For now, the process of fabricating the CMOS image sensor is finished.

In addition, a structure of the CMOS image sensor is disclosed in the US patent. (U.S. Pat. No. 6,838,742, hereafter '742) As shown in the FIG. 14, the structure includes: a substrate 210 comprising a multi-trench photodiode region 223. The photodiode region 223 includes a doping layer 223, an insulator 237 and a conductive layer 238. A conductor 218 is adjacent to the photodiode region 223. A N-type doping region 230 is positioned at a side of the conductor 218. The photodiode in '742 increases the surface of the photo sensor area with the multi-trench structure, so the sensitivity of the image sensor is increased. However, the fabricating process of the multi-trench photodiode is very complicated.

The conventional photodiodes mentioned above have several drawbacks as follows:

The lattice structure will be damaged easily during the high-energy implantation process. Therefore, the dark current will increase and the sensitivity of the photodiode will decrease. Because the depletion region (PN junction) in the conventional photodiode is located in the deep region of the substrate, light with short wavelength, such as blue light for instance, has a shallow penetration depth in the substrate, and the light current induced by the PN junction of the photo diode is small when the photodiode is irradiated by light of short wavelengths. Consequently, the sensitivity of the photodiode for detecting short wavelength light is reduced. So a new method to prevent the lattice structure of the photodiode from being damaged during the high-energy implantation process and keep the sensitivity from being reduced is needed.

### SUMMARY OF THE INVENTION

Therefore an improved photodiode is provided in the present invention to solve the above-mentioned problem.

According to the present invention, a method for fabricating a photodiode includes: first, a substrate comprising a well is provided, next, a first doping region is formed in the well, following that an epitaxial growth process is performed to form a conductive layer on the first doping region and the conductive layer is in-situ doped during the epitaxial growth process to form a second doping region on a surface of the conductive layer. Moreover, a third doping region in the well is achieved before forming the first doping region. Forming the third doping region in the well is by a threshold adjustment step.

According to a second embodiment of the present invention, another method for fabricating a photodiode includes: First, a substrate comprises at least a well is provided, then an epitaxial growth process is performed to form a conductive layer on the well and the conductive layer is in-situ doped during the epitaxial growth process to form a first doping region on a surface of the conductive layer. Following that an insulator on the conductor layer is formed, finally, a second doping region in the well under the conductive layer is formed.

The method for fabricating the photodiode in the present invention can prevent the lattice structure from being damaged during the high-energy implantation process. Therefore, the dark current can be reduced and the sensitivity of the photodiode will be increased. Moreover, the distance for the light current to the gate channel is reduced, therefore the signal can be sent more quickly. Furthermore, the surface of the photo sensor area of the photodiode in the present invention is increased, thus the sensitivity of the photodiode is increased as well. The depletion region of the photodiode in the present invention is near the surface of photo sensor area, thus the photodiode in the present invention has a better sensitivity to short wavelength light. In addition, because the depletion region of the photodiode in the present invention is far from the STI structure, the leakage between the photodiode and the STI structure can be reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1 to 6 are schematic diagrams of a fabrication method for a CMOS image sensor according to prior art.

FIGS. 7 to 13 show a fabrication method for a CMOS image sensor according to US publication No. 2006/0138471.

FIG. 14 shows a structure of the CMOS image sensor according to U.S. Pat. No. 6,838,742.

FIG. 15 to 19 are schematic diagrams illustrating the method for fabricating a photodiode in accordance with the first embodiment of the present invention.

FIG. 20 to 24 are schematic diagrams illustrating the method for fabricating a photodiode in accordance with the second embodiment of the present invention.

### DETAILED DESCRIPTION

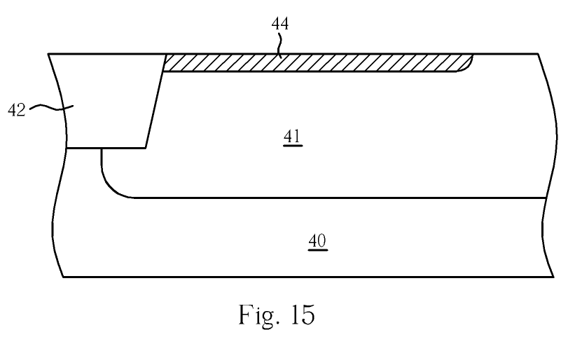

Please refer to FIG. 15 to FIG. 19. FIG. 15 to 19 are schematic diagrams illustrating the method for fabricating a photodiode in accordance with the first embodiment of the present invention.

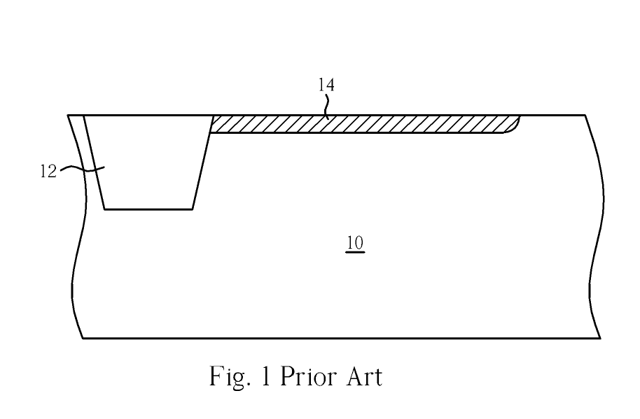

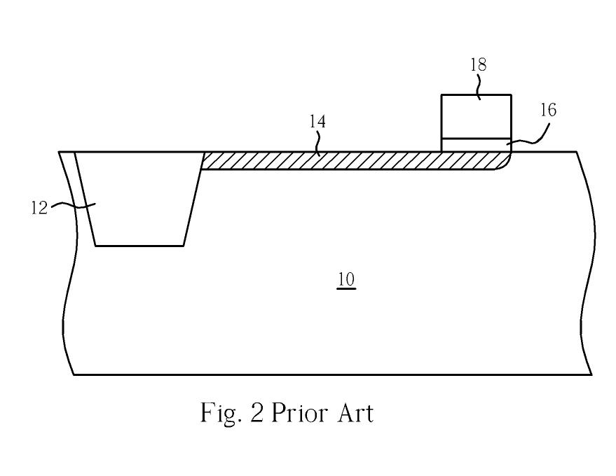

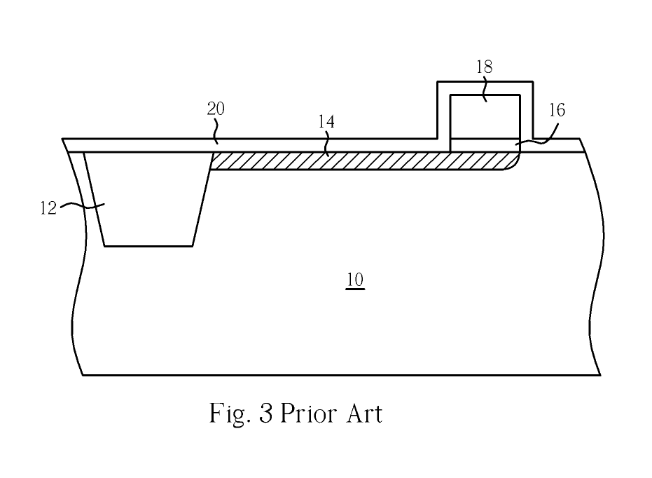

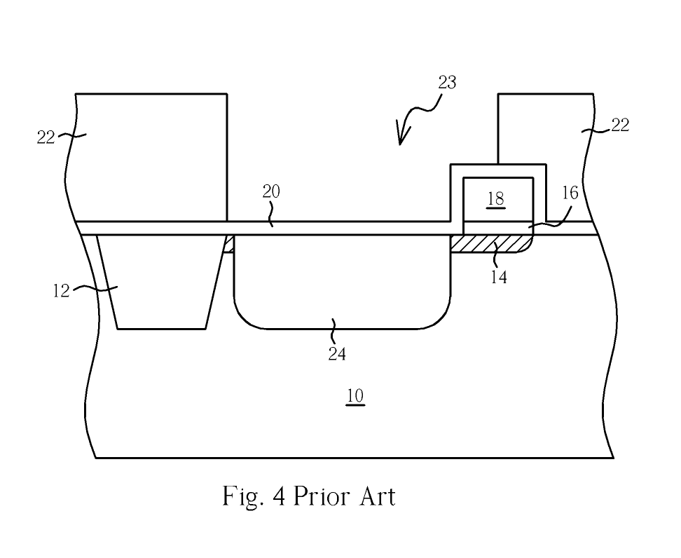

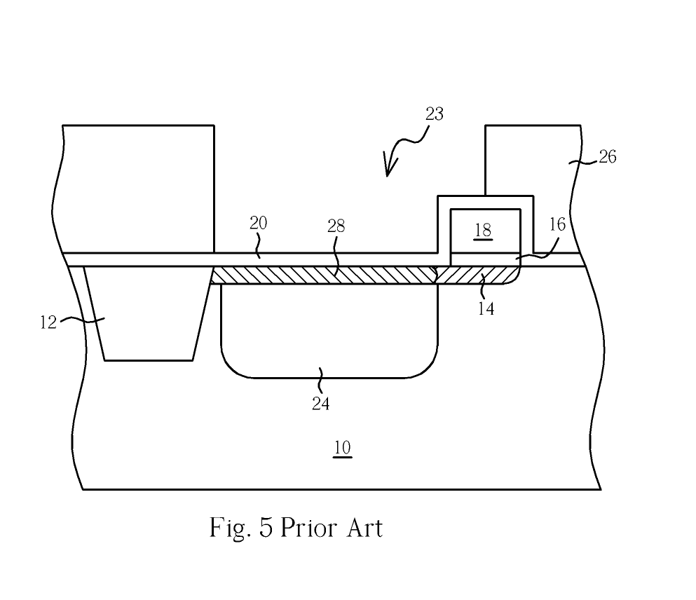

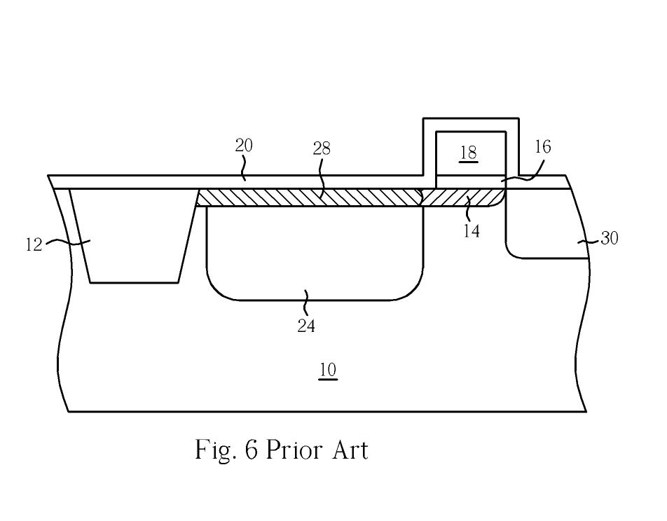

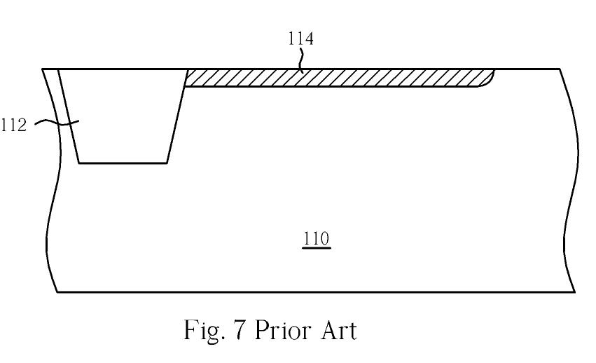

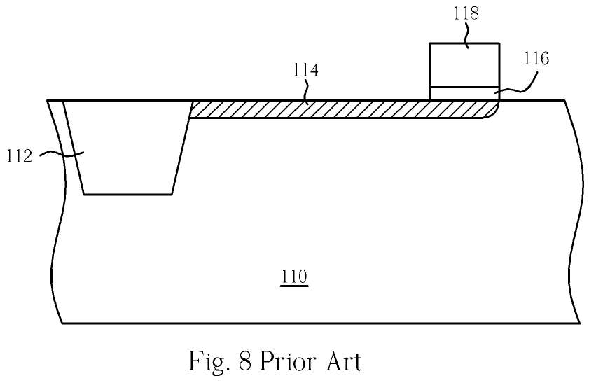

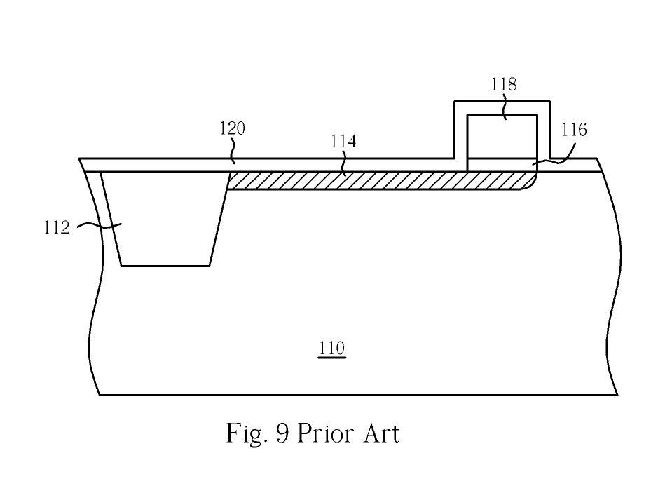

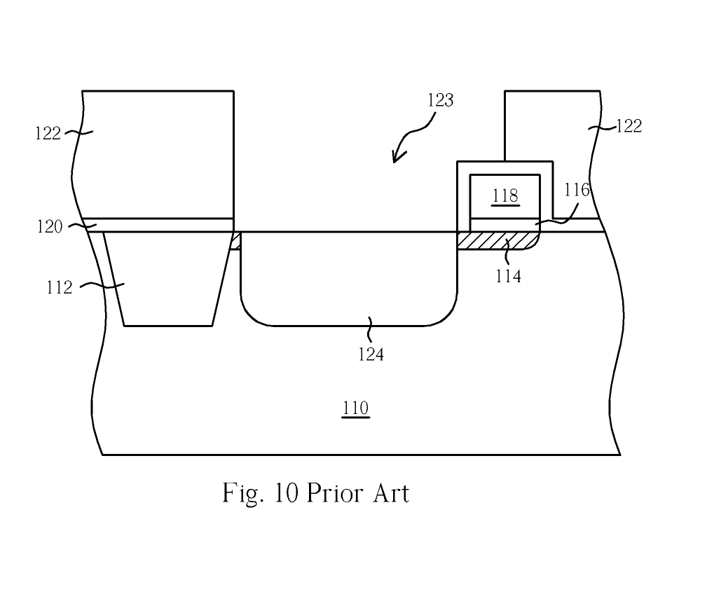

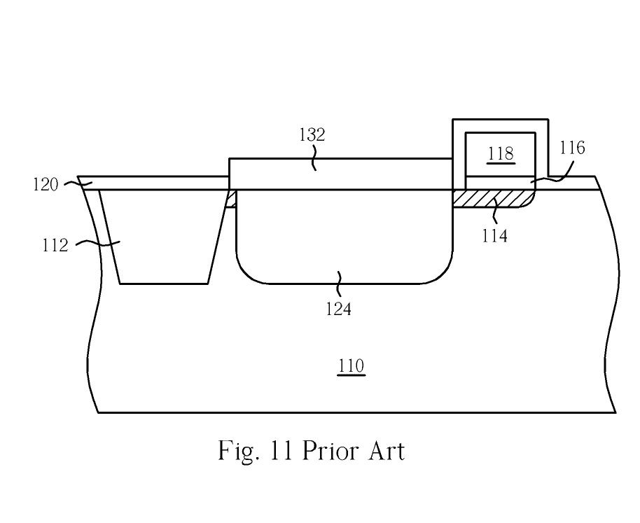

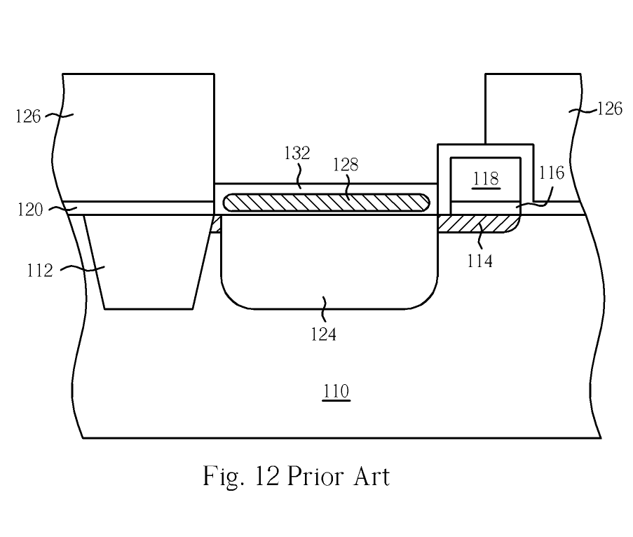

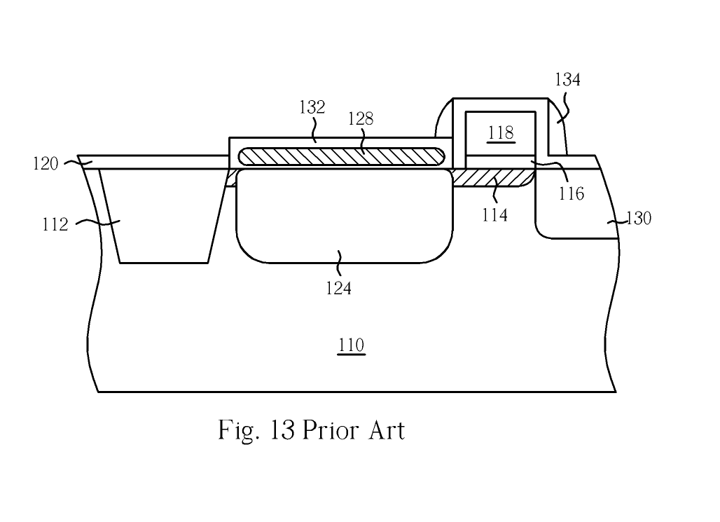

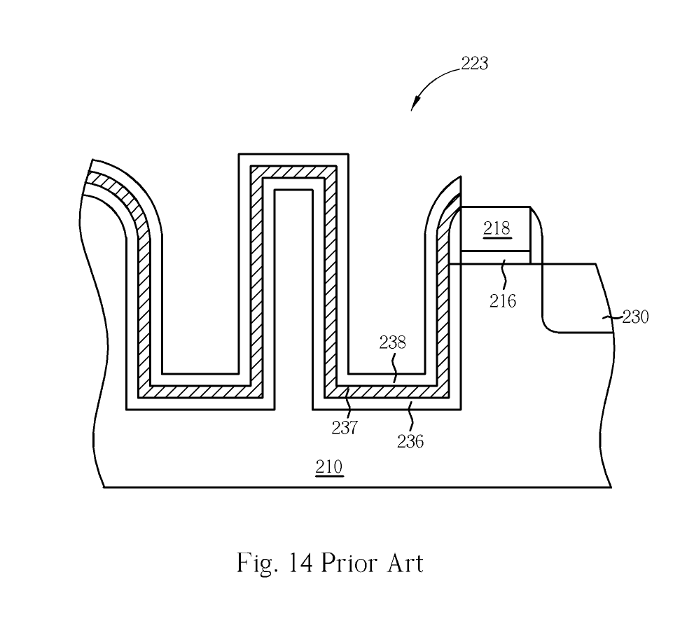

As shown in FIG. 1 5, first providing a substrate 40 comprises a P-type well 41 and a STI structure 42. These processes are well-known for those skilled in the art, for example, performing a well forming process, next, forming at least a trench (not shown) in the substrate 40 and forming an insulator (not shown) to cover the substrate 40 and filling up the trench. Following that, a STI structure 42 is formed in the substrate 40. The STI structure 42 isolates the unit pixels of the CMOS image sensor one from another. The STI structure can be replaced by other insulated structures such as field oxide. After that, a third doping region, the P-type doping region 44, is formed in the substrate 40 by the implantation process to adjust the threshold voltage of the transfer gate.

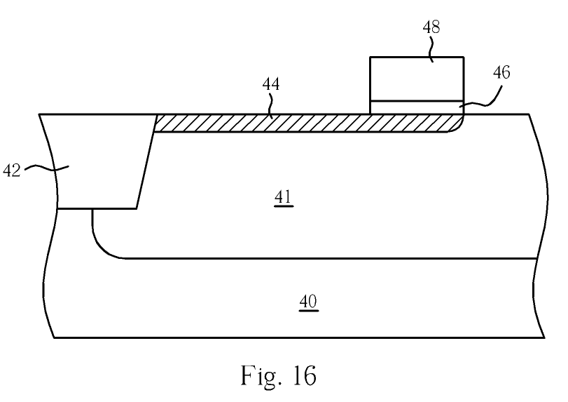

Referring to FIG. 16, a dielectric layer (not shown) is formed. The dielectric layer can be a silicon nitride layer forming by thermal oxidation, or any dielectric material forming by deposition. Then, a conductive layer (not shown) is formed on the dielectric layer. The conductive layer includes polysilicon, polycide, metal or metal alloys, among others. Following that, an etching process is performed to etch the dielectric layer and the conductive layer to form gates of every transistor on the substrate 40. For example, the transfer gate in the FIG. 16 includes an insulator 46 and a conductor 48.

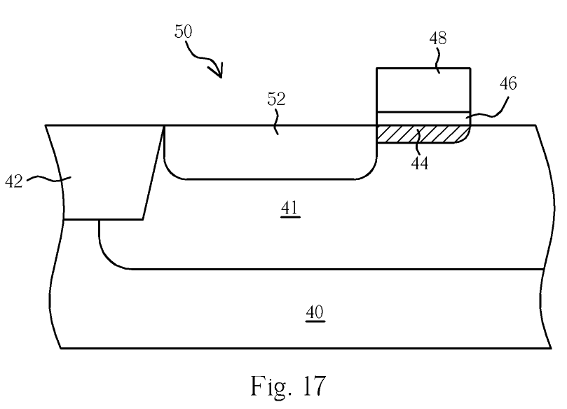

As shown in FIG. 17, the substrate 40, STI structure 42 and the conductor 48 are covered by a photoresist (not shown). Then, the photodiode region 50 is defined by an exposure process and a development process, and N-type dopants such as phosphorous or arsenic are implanted into the substrate 40 under the photodiode region 50 to form a first doping region, the N-type doping region 52, by the high-energy implantation process. By controlling the energy of the high-energy implantation process, the location of the N-type doping region 52 can be positioned nearer the surface of the substrate 40. The photoresist is removed after the implantation process is finished.

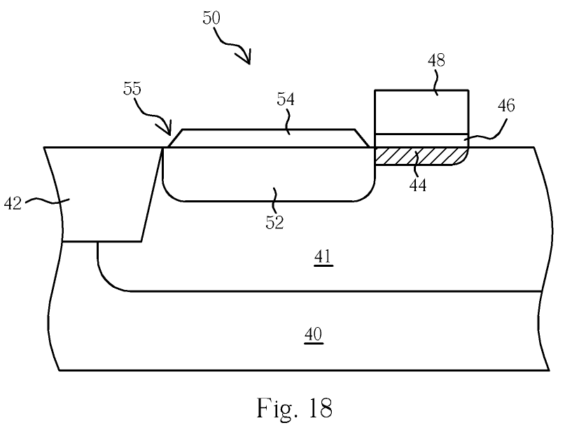

As shown in FIG. 18, an epitaxial growth process is performed to form a conductive layer. For example, a patterned mask (not shown) is formed to expose the photodiode region 50. Then, a gas phase epitaxy process is performed to form a single-crystal silicon layer 54. This process is well-known for those skilled in the art. Briefly speaking the process is a chemical gas deposition method of epitaxial growth of materials, especially compound semiconductors from the surface reaction of organic compounds or metalorganics and metal hydrides containing the required chemical elements such as silicon. In addition, the single-crystal silicon layer 54 is a three-dimensional trapezium comprising an edge area 55 positioned on the edge of the three-dimensional trapezium. The edge area 55 increases the surface of the photo sensor area. In addition, the shape of the single-crystal silicon layer 54 in the present invention can be any three-dimensional structure, and is not limited to the three-dimensional trapezium.

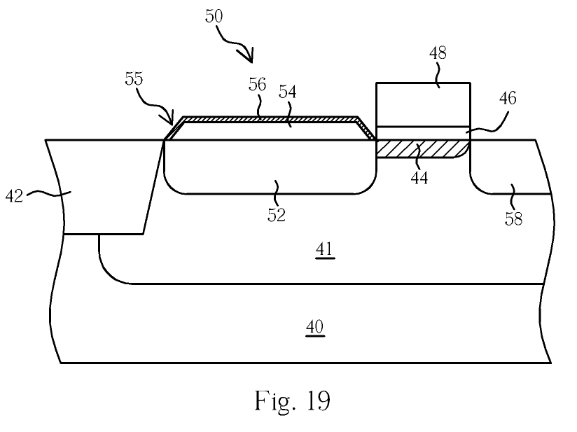

It is noteworthy that when performing the epitaxial growth process to a predetermined progress, which means the single-crystal silicon layer 54 grows to a predetermined height, in-situ putting the gas dopant to the epitaxial growth reactor, and the gas dopant will mix into the surface of growing single-crystal silicon layer 54 to form a second doping region, the doping region 56, as shown in FIG. 19. For now, the process of fabricating the photodiode is finished. For a preferred embodiment of the present invention, the gas dopant is P-type, which includes 3A groups dopant such as boron. Finally, a N-type doping region 58 is formed in the substrate 40 which is adjacent to a side of the conductor 48 by using a third photoresist (not shown) as mask. The N-type doping region 58 serves as a drain for the photodiode. For now, the process of fabricating the CMOS image sensor is finished.

The dopant in the surface of the photo sensor area is formed by in-situ doping the growing single-crystal silicon layer during epitaxial growth process. On the contrary, in the conventional process, the surface of the photo sensor area is formed in advance. Then, the dopant is implanted by the high-energy implantation process. Therefore, the lattice structure in the photo sensor area will inevitably be damaged, leading to an increase of dark current and a decrease of the sensitivity of the photodiode. The fabricating process disclosed in the present invention can improve the drawbacks mentioned-above.

Furthermore, by adding the single-crystal silicon layer, the edge area of the single-crystal silicon layer can increase the surface of the photo sensor area of the photodiode, thus the sensitivity of the photodiode is increased as well. The depletion region (PN junction) of the photodiode in the present invention is near the surface of photo sensor area, thus the photodiode in the present invention has a better sensitivity to short wavelength light, such as blue light. Moreover, the distance for the light current to the gate channel is reduced, therefore the signal can be sent more quickly. In addition, because the depletion region of the photodiode in the present invention is far from the STI structure, the leakage between the photodiode and the STI structure can be reduced.

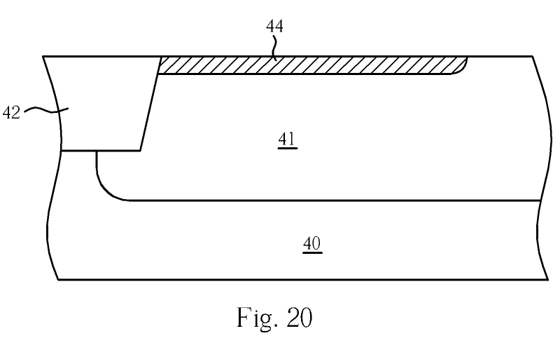

Please refer to FIG. 20 to FIG. 24. FIG. 20 to 24 are schematic diagrams illustrating the method for fabricating a photodiode in accordance with the second embodiment of the present invention.

As shown in FIG. 20, a substrate 40 comprising a P-type well 41 and a STI structure 42 is provided first. These processes are well-known for those skilled in the art, for example, performing a well forming process, next, forming at least a trench (not shown) in the substrate 40 and forming an insulator (not shown) to cover the substrate 40 and filling up the trench. Following that, a STI structure 42 is formed in the substrate 40. The STI structure isolates the unit pixels of the CMOS image sensor one from another. The STI structure can be replaced by other insulated structure such as field oxide. After that, a third doing region, the P-type doping region 44, is formed in the substrate 40 by the implantation process to adjust the threshold voltage of the transfer gate.

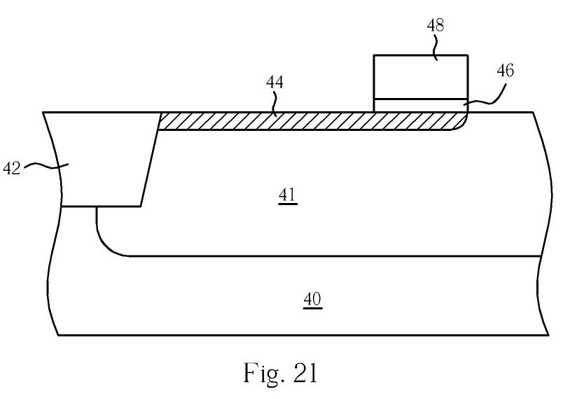

Referring to FIG. 21, a dielectric layer (not shown) is formed. The dielectric layer can be a silicon nitride layer forming by thermal oxidation, or any dielectric material formed by deposition. Then, a conductive layer (not shown) is formed on the dielectric layer. The conductive layer includes polysilicon, polycide, metal or metal alloys, among others. Following that, an etching process is performed to etch the dielectric layer and the conductive layer to form gates of every transistor on the substrate 40. For example, the transfer gate in the FIG. 21 includes an insulator 46 and a conductor 48.

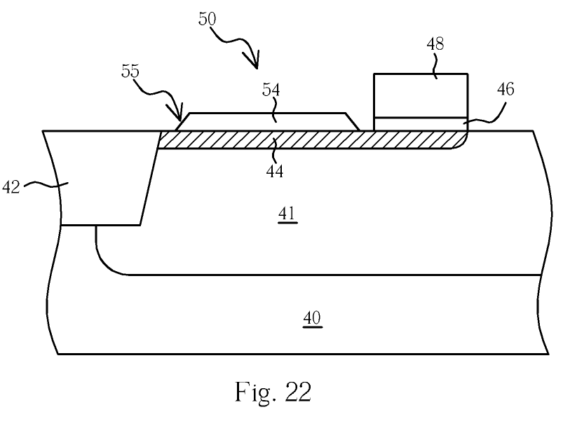

As shown in FIG. 22, an epitaxial growth process is performed to form a conductive layer. For example, a patterned mask (not shown) is formed to expose the photodiode region 50. Then, the gas phase epitaxy process is performed to form a single-crystal silicon layer 54. This process is well-known for those skilled in the art. Briefly speaking the process is a chemical gas deposition method of epitaxial growth of materials, especially compound semiconductors from the surface reaction of organic compounds or metalorganics and metal hydrides containing the required chemical elements such as silicon. In addition, the single-crystal silicon layer 54 is a three-dimensional trapezium comprising an edge area 55 positioned on the edge of the three-dimensional trapezium. The edge area 55 increases the photo sensor area. In addition, the shape of the single-crystal silicon layer 54 in the present invention can be any three-dimensional structure, and is not limited to the three-dimensional trapezium.

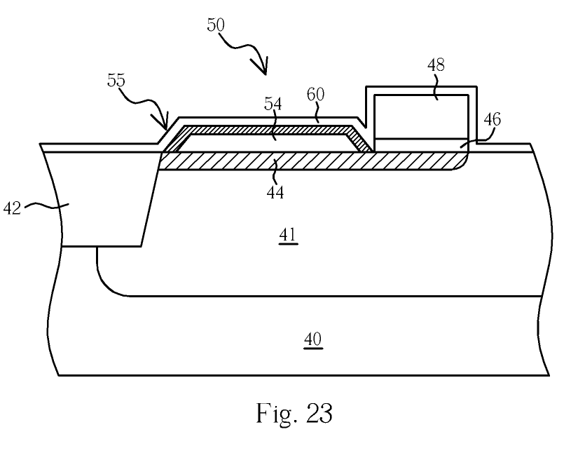

It is noteworthy that when performing the epitaxial growth process to a predetermined progress, which means the single-crystal silicon layer 54 grows to a predetermined height, in-situ putting the gas dopant to the epitaxial growth reactor, and the gas dopant will mix into the surface of growing single-crystal silicon layer 54 to form a first doping region, the doping region 56, as shown in FIG. 23. For a preferred embodiment of the present invention, the gas dopant is P-type, which includes 3A groups dopant such as boron. Next, an insulator 60 is formed on the single-crystal silicon layer 54 to be a sacrificing layer to prevent the lattice structure from being damaged by the following implantation process.

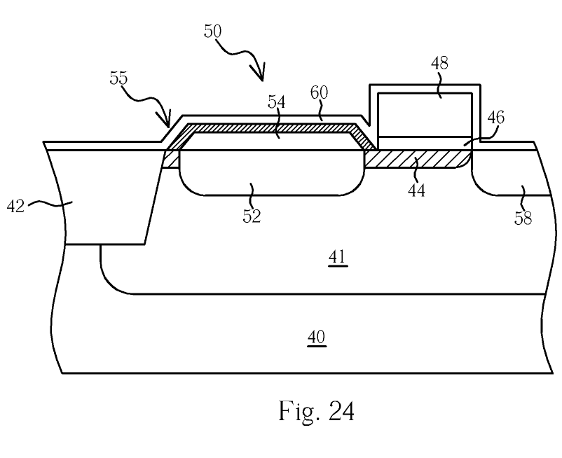

As shown in FIG. 24, the substrate 40, STI structure 42 and the conductor 48 are covered by a photoresist (not shown). Then, the photodiode region 50 is defined by an exposure process and a development process, and a N-type dopant such as phosphorous or arsenic is implanted into the substrate 40 under the photodiode region 50 to form a second doping region, the N-type doping region 52, by the high-energy implantation process. For now, the fabricating process of the photodiode is finished. The photoresist is removed after the implantation process. Then, a N-type doping region 58 is formed adjacent to a side of the conductor 48 to serve as a drain for the photodiode. For now, the process of fabricating the CMOS image sensor is finished. After that, the insulator 60 can be removed optionally. Because the single-crystal silicon layer 54 is on the doping region 52, the depth of the dopant in the doping region 52 will be closer to the surface of the substrate 40 after performing the implantation process. Thus, the distance between the PN junction and the surface of the substrate 40 is reduced.

In this embodiment, the surface of the photo sensor area is covered by the insulator before the implantation process, so the damage of the lattice structure caused by the high-energy implantation process will be reduced. On the contrary, there is not any sacrificing layer to protect the photo sensor area in the conventional process. So when implanting the dopant by high-energy implantation process, the lattice structure is inevitably damaged. Therefore, the dark current will increase. The fabricating process disclosed in the present invention can solve the above-mentioned problem.

Furthermore, by adding the single-crystal silicon layer, the edge area of the single-crystal silicon layer can increase the photo sensor area of the photodiode, thus the sensitivity of the photodiode is increased as well. The depletion region (PN junction) of the photodiode in the present invention is near the surface of photo sensor area, thus the photodiode in the present invention has a better sensitivity to short wavelength light, such as blue light. Moreover, the distance for the light current to the gate channel is reduced, therefore the signal can be sent more quickly. In addition, because the depletion region of the photodiode in the present invention is far from the STI structure, the leakage between the photodiode and the STI structure can be reduced.

Those skilled in the art will readily observe that numerous modifications and alterations of the device and method may be made while retaining the teachings of the invention.

What is claimed is:

1. A method of fabricating a photodiode, comprising:
providing a substrate comprising at least a well;
forming a first doping region in the well; and
performing an epitaxial growth process to form a conductive layer on the first doping region and in-situ doping the conductive layer during the epitaxial growth process to form a second doping region on a surface of the conductive layer.

2. The method of claim 1, wherein the well is P-type.

3. The method of claim 2, wherein the first doping region is N-type.

4. The method of claim 2, wherein the second doping region is P-type.

5. The method of claim 2, further comprising forming a third doping region in the well before the first doping region is formed, wherein forming the third doping region in the well is by a threshold adjustment step.

6. The method of claim 5, wherein the third doping region is P-type.

7. The method of claim 1, wherein the conductive layer comprises single-crystal silicon.

8. A method of fabricating a photodiode, comprising:
providing a substrate comprising at least a well;
performing an epitaxial growth process to form a conductive layer on the well and in-situ doping the conductive layer during the epitaxial growth process to form a first doping region on a surface of the conductive layer;
forming an insulator on the conductive layer; and
forming a second doping region in the well under the conductive layer.

9. The method of claim 8, further comprising removing the insulator after the second doping region is formed.

10. The method of claim 8, wherein the well is P-type.

11. The method of claim 10, wherein the first doping region is P-type.

12. The method of claim 10, wherein the second doping region is N-type.

13. The method of claim 10, further comprising forming a third doping region in the well before the first doping region is formed, wherein forming the third doping region in the well is by a threshold adjustment step.

14. The method of claim 13, wherein the third doping region is P-type.

15. The method of claim 8, wherein the conductive layer comprises single-crystal silicon.
